(19) United States
(12) Patent Application Publication
(10) Pub. No.: US 2014/0097418 A1
(43) Pub. Date: Apr. 10, 2014

(54) ORGANIC LIGHT EMITTING DIODE DISPLAY AND METHOD FOR MANUFACTURING THE SAME

(71) Applicant: Samsung Display Co., Ltd., Yongin-City (KR)

(72) Inventor: Hyun-Won KIM, Yongin-City (KR)

(73) Assignee: Samsung Display Co., Ltd., Yongin-City (KR)

(21) Appl. No.: 13/956,893

(22) Filed: Aug. 1, 2013

(30) Foreign Application Priority Data
Oct. 4, 2012 (KR) 10-2012-0110087

(51) Int. Cl. H01L 51/52

(52) U.S. Cl. CPC H01L 51/5237
USPC 257/40; 438/28

(57) ABSTRACT

An organic light emitting diode (OLED) display including a substrate, a plurality of organic light emitting diodes placed on the substrate and each configured to include a first electrode, an organic emission layer, and a second electrode, a filling film placed on the substrate and configured to include an opening corresponding to the organic light emitting diode, and a sealing member formed on the filling film.

### CROSS-REFERENCE TO RELATED APPLICATIONS

This application claims priority to and the benefit of Korean Patent Application No. 10-2012-0110087 filed in the Korean Intellectual Property Office on Oct. 4, 2012, the entire contents of which are incorporated herein by reference.

### BACKGROUND

1. Field

The described technology relates generally to an organic light emitting diode (OLED) display and a method of manufacturing the same.

2. Description of the Related Art

An organic light emitting diode (OLED) display is a self-light emitting type display device that displays an image using organic light emitting diodes for emitting light. The organic light emitting diode (OLED) display can have reduced thickness and weight because it does not need an additional light source unlike a liquid crystal displays (LCD). Furthermore, the organic light emitting diode (OLED) display has been in the spotlight as the next-generation display device of a portable electronic device because it shows high quality characteristics, such as low power consumption, high luminance, and a high reaction speed.

The pixel substrate of the organic light emitting diode (OLED) display is sealed by an encapsulation substrate in order to protect the pixels. Here, a filling agent is placed between the encapsulation substrate and a pixel substrate, and the filling agent prevents cathodes from being peeled off and buffers physical impact applied from the encapsulation substrate to the pixel substrate.

The encapsulation substrate is formed by attaching a filling adhesion film on the entire surface of the pixel substrate and curing the filling adhesion film.

The above information disclosed in this Background section is only for enhancement of understanding of the background of the described technology and therefore it may contain information that does not form the prior art that is already known in this country to a person of ordinary skill in the art.

### SUMMARY

If there are impurities in a filling adhesion film, the impurities can be pressurized by the filling adhesion film, thereby being capable of damaging other layers.

Particularly, if there are impurities in an emission layer, the emission layer can be damaged, thereby being capable of generating a black spot defect in the display.

The described technology has been made in an effort to provide an organic light emitting diode (OLED) display and a method of manufacturing the same having an advantage of preventing a defect, such as a black spot due to impurities, by solving damage to an emission layer due to the impurities.

An example embodiment provides an organic light emitting diode (OLED) display, including a substrate, a plurality of organic light emitting diodes placed on the substrate and each configured to include a first electrode, an organic emission layer, and a second electrode, a filling film placed on the substrate and configured to include an opening corresponding to the organic light emitting diode, and a sealing member formed on the filling film.

The filling film may be made of any one of epoxy, acryl, and silicon materials.

Another embodiment provides an organic light emitting diode (OLED) display, including a substrate, a first thin film transistor placed on the substrate, a first electrode connected to the first thin film transistor, a pixel definition film placed on the first electrode and configured to comprise an opening through which the first electrode is exposed, an emission layer placed on the exposed first electrode, a second electrode placed on the emission layer and the pixel definition film, a filling film placed on the second electrode corresponding to the pixel definition film, and a sealing member placed on the filling film.

The filling film may have a plane pattern identical with the pixel definition film.

The pixel definition film may include a horizontal part and a vertical part crossing each other, and the filling film may correspond to any one of the horizontal part or the vertical part.

The filling film may be made of any one of epoxy materials, acryl materials, and silicon materials.

Yet another embodiment provides a method of manufacturing an organic light emitting diode (OLED) display, including fabricating an organic light emitting substrate comprising a light emitting diode, forming a filling film by transferring a filling adhesion film, comprising openings, on a second electrode of the organic light emitting substrate, and disposing a sealing member on the filling film and coalescing the sealing member and the organic light emitting substrate, wherein the opening is formed to correspond to the at least one light emitting diode.

Further yet another embodiment provides a method of manufacturing an organic light emitting diode (OLED) display, including fabricating an organic light emitting substrate comprising a light emitting diode, forming a filling film, comprising an opening, on a second electrode of the organic light emitting diode using a liquid filling agent by using a nozzle printing or photolithography process, disposing a sealing member on the filling film and coalescing the sealing member and the organic light emitting substrate, wherein the opening is formed to correspond to the at least one light emitting diode.

The filling film may be made of any one of epoxy materials, acryl materials, and silicon materials.

The light emitting diode may include a first electrode, an organic emission layer, and a second electrode, the organic light emitting substrate may further include a pixel definition film configured to define a position where the organic emission layer and comprising a vertical part and a horizontal part crossing each other, and the filling film may be formed in a position corresponding to any one of the horizontal part and the vertical.

When the filling film is formed to include the opening as in the present embodiments, the sealing member prevents impurities, placed in the organic emission layer, from being pressurized when the filling film is pressurized.

Accordingly, the organic light emitting diode (OLED) display not including a black spot resulting from impurities and a method of manufacturing the same can be provided.

### BRIEF DESCRIPTION OF THE DRAWINGS

FIG. 1 is a schematic cross-sectional view of an organic light emitting diode (OLED) display in accordance with an example embodiment.

FIGS. 2A to 2E are top plan views of a filling film shown in FIG. 1.

FIG. 3 is an equivalent circuit diagram of one of the pixels of an organic light emitting diode (OLED) display in accordance with an example embodiment.

FIG. 4 is a cross-sectional view of an organic light emitting diode (OLED) display in accordance with an example embodiment.

FIGS. 5 to 7 are cross-sectional views illustrating a method of manufacturing the organic light emitting diode (OLED) display in accordance with an example embodiment.

### DETAILED DESCRIPTION OF THE PREFERRED EMBODIMENT

The present embodiments will be described more fully hereinafter with reference to the accompanying drawings, in which example embodiments are shown. As those skilled in the art would realize, the described embodiments may be modified in various different ways, all without departing from the spirit or scope of the present embodiments.

In the drawings, the thickness of layers, films, the panels, regions, etc., are exaggerated for clarity. Like reference numerals designate like elements throughout the specification. It will be understood that when an element such as a layer, film, region, or the substrate is referred to as being “on” another element, it can be directly on the other element or intervening elements may also be present. In contrast, when an element is referred to as being “directly on” another element, there are no intervening elements present.

Organic light emitting diode (OLED) displays in accordance with some example embodiments are described in detail with reference to the accompanying drawings.

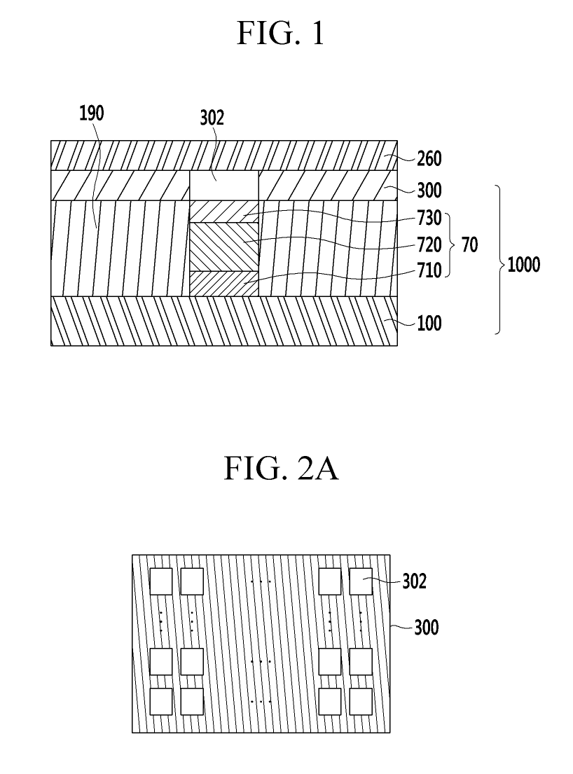

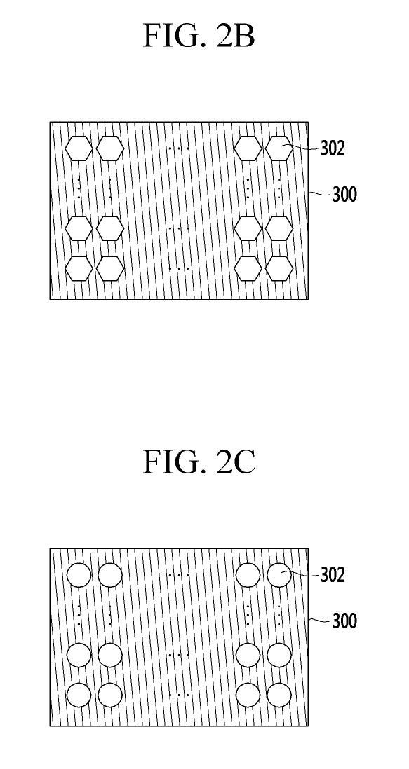

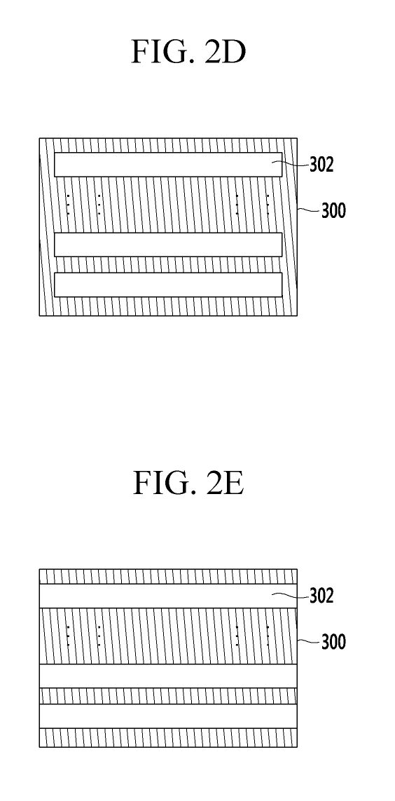

FIG. 1 is a schematic cross-sectional view of an organic light emitting diode (OLED) display in accordance with an example embodiment, and FIG. 2 is a top plan view of a filling film shown in FIG. 1.

As shown in FIG. 1, the organic light emitting diode (OLED) display in accordance with an example embodiment includes a panel 1000 configured to include a light emitting diode 70, a filling film 300 placed on the panel 1000, and a sealing member 260 placed on the filling film 300.

The panel 1000 includes a substrate 100 and a plurality of pixels placed on the substrate 100 and configured to form a matrix. Each of the pixels includes the light emitting diode 70 and a thin film transistor (not shown) connected to the light emitting diode 70.

The sealing member 260 is coalesced and sealed with the panel 1000 and configured to protect the organic light emitting diode 70. The sealing member 260 can comprise a transparent and insulating substrate made of glass, quartz, ceramic, or polymer resin.

The sealing member 260 is coalesced and sealed with the panel 1000 through a sealant (not shown) that is formed along the edge of the panel 1000.

The light emitting diode 70 includes a first electrode 710, an organic emission layer 720, and a second electrode 730.

The filling film 300 includes a plurality of openings 302, each having a region corresponding to the light emitting diode 70 of the panel 1000 opened, and fills a space between the panel 1000 and the sealing member 260. The filling film 300 can be made of any one of epoxy materials, acryl materials, and silicon materials.

The opening 302 can be formed to have the same shape as the plane of the light emitting diode 70 or can have a polygon, such as a square, quadrangle or a pentagon, or a circle, as shown in FIGS. 2A to 2E. In this case, the filling film 300 or the sealing member 70 prevents pressure from being applied to the light emitting diode 70. Accordingly, the opening 302 may have any form which prevents pressure, applied to the filling film 300 or the sealing member 260, from being transferred to the light emitting diode 70.

When the openings 302 are formed as in the example embodiment, the filling film 300 prevents pressure from being applied to the light emitting diode 70. Accordingly, the occurrence of a black spot due to impurities can be prevented because the impurities are not pressurized even when the impurities are present in the organic emission layer 720, the first electrode 710, and the second electrode 730 of the light emitting diode 70.

Reference numeral 190 (not described) refers to a pixel definition film that defines a region where the light emitting diode 70 is formed.

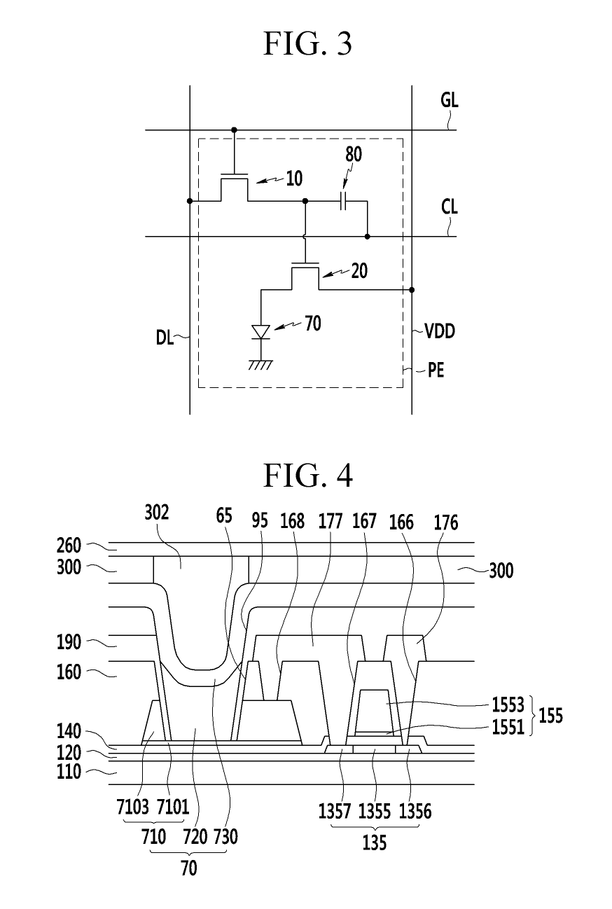

The above-described organic light emitting diode (OLED) display is described in detail below with reference to FIGS. 3 and 4.

FIG. 3 is an equivalent circuit diagram of one of the pixels of an organic light emitting diode (OLED) display in accordance with an example embodiment.

As shown in FIG. 3, the pixel PE has a 2Tr-1 Cap structure including the organic light emitting diode 70, first and two thin film transistors (TFTs) 10 and 20, and one capacitor 80. However, the example embodiment is not limited to the structure. For example, the pixel PE may include three or more thin film transistors and two or more capacitors and may have a variety of structures further including an additional wire thereto. The thin film transistors and capacitors additionally formed may be the elements of a compensation circuit.

The compensation circuit suppresses deviation from occurring in image quality by improving the uniformity of the organic light emitting diode 70 formed in each pixel PE. In general, the compensation circuit includes 2 to 8 thin film transistors.

The organic light emitting diode 70 includes an anode electrode, for example, a hole injection electrode, a cathode electrode, for example, an electron injection electrode, and an organic emission layer disposed between the anode electrode and the cathode electrode. The anode and the cathode may be the first electrode and the second electrode of FIG. 1.

In an example embodiment, one pixel PE includes the first thin film transistor 10 and the second thin film transistor 20.

Each of the first thin film transistor 10 and the second thin film transistor 20 includes a gate electrode, a semiconductor layer, a source electrode, and a drain electrode. Furthermore, the semiconductor layer of at least one of the first thin film transistor 10 and the second thin film transistor 20 includes a polysilicon film into which impurities are doped.

At least one of the first thin film transistor 10 and the second thin film transistor 20 is a polysilicon thin film transistor.

Although FIG. 3 illustrates a capacitor line CL along with a gate line GL, a data line DL, and a common power line VDD, the capacitor line CL may be omitted according to circumstances.

The source electrode of the first thin film transistor 10 is connected to the data line DL, and the gate electrode of the first thin film transistor 10 is connected to the gate line GL.

Furthermore, the drain electrode of the first thin film transistor 10 is connected to the capacitor line CL through the capacitor 80. A node is formed between the drain electrode of the first thin film transistor 10 and the capacitor 80 and connected to the gate electrode of the second thin film transistor 20. Furthermore, the common power line VDD is connected to the source electrode of the second thin film transistor 20, and the anode electrode of the organic light emitting diode 70 is connected to the drain electrode of the second thin film transistor 20.

The first thin film transistor 10 is used as a switch for selecting a pixel PE from which light will be emitted. The first thin film transistor 10 is instantly turned on, and thus the capacitor 80 is charged. Here, the amount of electric charges charged is proportional to the potential of voltage supplied from the data line DL. Furthermore, when a signal whose voltage is increased in one frame cycle is inputted to the capacitor line CL in the state in which the first thin film transistor 10 is turned off, the gate potential of the second thin film transistor 20 rises in response to the level of voltage supplied through the capacitor line CL on the basis of potential charged into the capacitor 80. Furthermore, the second thin film transistor 20 is turned on when the gate potential exceeds a threshold voltage. Then, the voltage supplied to the common power line VDD is supplied to the organic light emitting diode 70 through the second thin film transistor 20, and thus the organic light emitting diode 70 emits light.

A construction between the layers of one pixel of the organic light emitting diode (OLED) display in accordance with an example embodiment is described in detail below with reference to FIG. 4.

FIG. 4 is a cross-sectional view of an organic light emitting diode (OLED) display in accordance with an example embodiment.

The second thin film transistor 20 and the organic light emitting diode 70 of FIG. 3 are described in detail below according to order of a stack with reference to FIG. 4. The second thin film transistor 20 is hereinafter referred to as a thin film transistor.

The substrate 110 can be an insulating substrate made of glass, quartz, or ceramic.

A buffer layer 120 for preventing the infiltration of unnecessary components, such as impurities or moisture, and also making flat a surface is formed on the substrate 110. The buffer layer 120 can be made of at least one of silicon oxide (SiO₂) and silicon nitride (SiNx).

A semiconductor layer 135 made of polysilicon is formed on the buffer layer 120.

The semiconductor layer 135 is divided into a channel region 1355 and a source region 1356 and a drain region 1357 formed on both sides of the channel region 1355. The channel region 1355 of the semiconductor layer 135 is an intrinsic semiconductor layer made of polysilicon into which impurities are not doped. Each of the source region 1356 and the drain region 1357 of the semiconductor layer 135 is an impurity semiconductor layer made of polysilicon into which conductive impurities are doped.

The impurities doped into the source region 1356 and the drain region 1357 may have either p-type impurities or n-type impurities.

A gate insulating layer 140 is formed on the semiconductor layer 135. The gate insulating layer 140 can have a single layer or a multi-layer including at least one of tetraethylorthosilicate, TEOS), silicon oxide (SiO₂), and silicon nitride (SiNx).

A gate electrode 155 and a pixel electrode 710 are formed on the gate insulating layer 140. The gate electrode 155 overlaps with the channel region 1355, and the pixel electrode 710 can be the first electrode of FIG. 1.

The gate electrode 155 includes a first lower metal layer 1551 and a first upper metal layer 1553, and the pixel electrode 710 includes a first lower metal layer 7101 and a second upper metal layer 7103.

The first lower metal layer 1551 and the second lower metal layer 7101 may be made of material, such as indium tin oxide (ITO), indium zinc oxide (IZO), zinc oxide (ZnO), or indium oxide (In₂O₃), for example, a transparent conductive material.

The first upper metal layer 1553 and the second upper metal layer 7103 may be made of molybdenum, a molybdenum alloy, tungsten, or a tungsten alloy.

An interlayer insulating layer 160 and the gate insulating layer 140 include a source contact hole 166 and a drain contact hole 167 through which the source region 1356 and the drain region 1357 are exposed, respectively. Furthermore, the interlayer insulating layer 160 and the second upper metal layer 7103 includes an opening 65 through which the second lower metal layer 7101 is exposed.

A source electrode 176 and a drain electrode 177 are formed on the interlayer insulating layer 160. The source electrode 176 is connected to the source region 1356 through the source contact hole 166. Furthermore, the drain electrode 177 are electrically connected to the drain region 1357 and the second upper metal layer 7103 through the drain contact hole 167 and a pixel contact hole 168. The pixel electrode 710 is connected to the drain electrode 177, thus becoming the anode electrode of the organic light emitting diode. The pixel electrode 710 may be connected to the source electrode (not shown).

A pixel definition film 190 is formed on the interlayer insulating layer 160.

The pixel definition film 190 has an opening 95 through the second lower metal layer 7101 is exposed through the opening 65. The pixel definition film 190 may include resin, such as polyacrylates or polyimides, and a silica-based inorganic substance.

An organic emission layer 720 is formed in the opening 95 of the pixel definition film 190.

The organic emission layer 720 includes a plurality of layers including one or more of an emission layer, a hole-injection layer (HIL)), a hole transport layer (HTL), an electron transport layer (ETL), and an electron injection layer (EIL).

If the organic emission layer 720 includes all of them, the hole injection layer (HIL) can be placed on the pixel electrode 710, for example, the anode, and the hole transport layer (HTL), the emission layer, the electron transport layer (ETL), and the electron injection layer (EIL) can be sequentially stacked over the hole injection layer (HIL).

A common electrode 730 is formed on the pixel definition film 190 and the organic emission layer 720.

The common electrode 730 can be the second electrode of FIG. 1, and the common electrode 730 becomes the cathode of the organic light emitting diode. Accordingly, the pixel electrode 710, the organic emission layer 720, and the common electrode 730 form an organic light emitting diode 70.

The common electrode 730 can be a reflective layer or a semi-transmission film made of at least one of magnesium (Mg), silver (Ag), gold (Au), calcium (Ca), lithium (Li), chromium (Cr), and aluminum (Al) or an alloy thereof

Furthermore, the common electrode 730 can be a semi-transparent film, such as the second lower metal layer 7101 of the pixel electrode 710.

A filling film 300 is formed on the common electrode 730. The filling film 300 includes an opening 302, such as that shown in FIGS. 2A to 2E. The opening 302 corresponds to the organic light emitting diode 70.

A sealing member 260 is placed on the filling film 300.

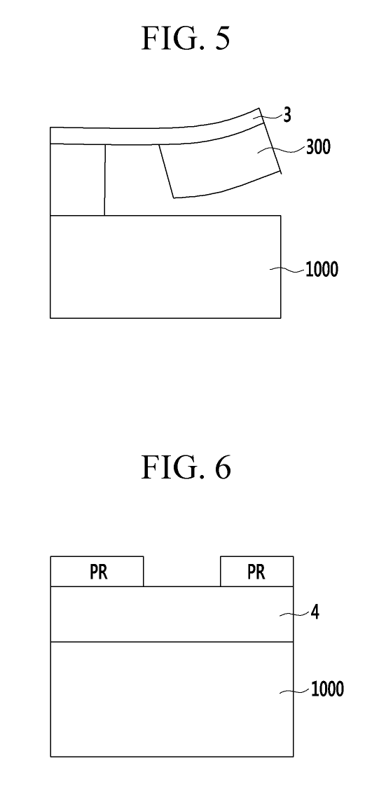

A method of the above-described organic light emitting diode (OLED) display is described in detail with reference to FIGS. 5 to 7.

FIGS. 5 to 7 are cross-sectional views illustrating a method of manufacturing the organic light emitting diode (OLED) display in accordance with an example embodiment.

First, the panel 1000 including a pixel including the light emitting diode 20 is prepared. Furthermore, the filling film 300 is formed on the panel 1000.

The filling film 300, as shown in FIG. 5, can be transferred on the panel 1000 in the state in which the filling film 300 is attached to a releasing paper 3 in the form of a film including the opening 302.

Next, as shown in FIG. 1, the sealing member 260 is disposed on the filling film 300 and sealed along with the panel 1000.

Since the opening 302 of the filling film 300 is placed in a region corresponding to the light emitting diode 70, pressure applied to impurities placed in the organic light emitting diode 70 is not transferred the light emitting diode 70. Accordingly, since the organic light emitting diode 70 is not pressurized even when there are impurities occurring in a process, a light emitting defect, such as a black spot, is not generated.

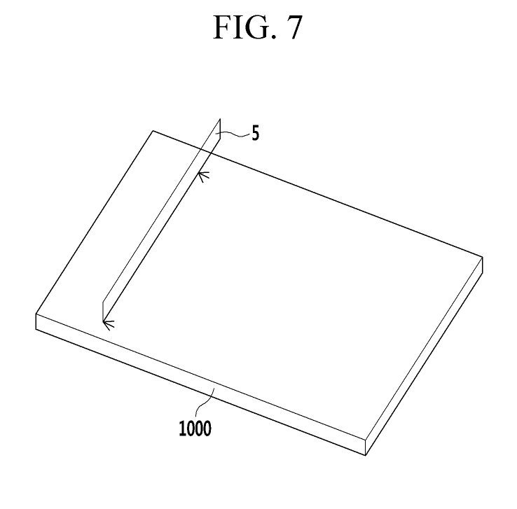

The filling film 300 can be formed using a method, such as that described with reference to FIGS. 6 and 7.

Referring to FIG. 6, a resin layer 4 for filling is formed by coating resin for filling on the panel 1000. A photoresist pattern PR is formed on the resin layer for filling 4. The filling film 300 can be formed by etching the resin layer 4 using the photoresist pattern as a mask.

In some embodiments, as shown in FIG. 7, the filling film 300 can be formed by coating a resin for filling liquid on the panel 1000 using a nozzle 5.

The example embodiments have been described in detail, but the scope of the present embodiments is not limited thereto. The scope of the present embodiments also includes a variety of modifications and changes of a person having ordinary skill in the art which are defined in the appended claims.

While this disclosure has been described in connection with what is presently considered to be practical example embodiments, it is to be understood that the present embodiments are not limited to the disclosed embodiments, but, on the contrary, is intended to cover various modifications and equivalent arrangements included within the spirit and scope of the appended claims.

What is claimed is:

1. An organic light emitting diode (OLED) display, comprising:
a substrate,
a plurality of organic light emitting diodes placed on the substrate and each configured to include a first electrode, an organic emission layer, and a second electrode,
a filling film on the substrate comprising an opening corresponding to at least one organic light emitting diode, and
a sealing member on the filling film.

2. The organic light emitting diode (OLED) display of claim 1, wherein the filling film comprises at least one of epoxy materials, acryl materials, and silicon materials.

3. The organic light emitting diode (OLED) display of claim 1, wherein the opening has the same shape as the at least one organic light emitting diode.

4. The organic light emitting diode (OLED) display of claim 1, wherein the opening has a polygon shape.

5. The organic light emitting diode (OLED) display of claim 4, wherein the opening has a shape of a square, quadrangle, pentagon, or circle.

6. An organic light emitting diode (OLED) display, comprising:
a substrate,
a first thin film transistor on the substrate,
a first electrode connected to the first thin film transistor,
a pixel definition film on the first electrode comprising an opening through which the first electrode is exposed,
an emission layer on the exposed first electrode,
a second electrode on the emission layer and the pixel definition film,
a filling film on the second electrode corresponding to the pixel definition film, and
a sealing member on the filling film.

7. The organic light emitting diode (OLED) display of claim 6, wherein the opening has the same shape as the at least one organic light emitting diode.

8. The organic light emitting diode (OLED) display of claim 6, wherein the opening has a polygon shape.

9. The organic light emitting diode (OLED) display of claim 8, wherein the opening has a shape of a square, quadrangle, pentagon, or circle.

10. The organic light emitting diode (OLED) display of claim 6, wherein the filling film has a plane pattern identical to the pixel definition film.

11. The organic light emitting diode (OLED) display of claim 6, wherein:
the pixel definition film comprises a horizontal part and a vertical part crossing each other, and
the filling film corresponds to any one of the horizontal part or the vertical part.

12. The organic light emitting diode (OLED) display of claim 6, wherein the filling film comprises at least one of epoxy materials, acryl materials, and silicon materials.

13. A method of manufacturing an organic light emitting diode (OLED) display
fabricating an organic light emitting substrate comprising a light emitting diode,
forming a filling film, comprising an opening, on a second electrode of the organic light emitting diode using a liquid filling agent by using a nozzle printing or photolithography process, and
disposing a sealing member on the filling film and coalescing the sealing member and the organic light emitting substrate,
wherein the opening is formed to correspond to at least one light emitting diode.

14. The method of claim 13, wherein the filling film is made of any one of epoxy materials, acryl materials, and silicon materials.

15. The method of claim 13, wherein:
the light emitting diode comprises a first electrode, an organic emission layer, and a second electrode,
the organic light emitting substrate further comprises a pixel definition film configured to define a position where the organic emission layer and comprising a vertical part and a horizontal part crossing each other, and
the filling film is formed in a position corresponding to any one of the horizontal part and the vertical.
